(19) United States
(12) Patent Application Publication
(10) Pub. No.: US 2024/0341066 A1
(43) Pub. Date: Oct. 10, 2024

(54) APPARATUS FOR PROVIDING THERMAL MANAGEMENT AND ELECTROMAGNETIC INTERFERENCE SHIELDING

(71) Applicant: Thomson Licensing, Cesson-Sevigne (FR)

(72) Inventors: Lizhi ZHAO, Beijing (CN); Ming LI, Beijing (CN)

(21) Appl. No.: 18/681,945

(22) PCT Filed: Aug. 30, 2021
(86) PCT No.: PCT/CN2021/115390

§ 371 Date: Feb. 7, 2024

(51) Int. Cl. H05K 7/20; H05K 9/00

(52) U.S. Cl. CPC H05K 7/20418; H05K 7/20454; H05K 9/0032

(57) ABSTRACT

An apparatus is described. The apparatus includes a shield enclosing a component attached to a circuit board and having an inner surface and outer surface, the component having an outer surface aligned in parallel with the shield inner surface of the shield, the shield including at least one opening extending through the shield from the outer surface to the inner surface and aligned with the component. The apparatus includes a heatsink positioned adjacent to the outer surface of the shield and aligned with the component, the heatsink thermally coupled to the outer surface of the component using flowable thermally conductive material that extends through the opening(s) and occupies a space between the outer surface of the component and the shield inner surface and a space between the shield outer surface and a surface of the heatsink. The apparatus may be assembled and used as part of an electronic device.

### TECHNICAL FIELD

The present disclosure relates to electronic devices having one or more components requiring heat dissipation as well as electromagnetic interference (EMI) shielding. More particularly, the present disclosure relates to a printed circuit board (PCB) EMI shield design that provides component heat transfer/dissipation away from one or more components mounted to the PCB.

### BACKGROUND

Any background information described herein is intended to introduce the reader to various aspects of art, which may be related to the present embodiments that are described below. This discussion is believed to be helpful in providing the reader with background information to facilitate a better understanding of the various aspects of the present disclosure. Accordingly, it should be understood that these statements are to be read in this light.

Thermal management remains a significant challenge in electronic devices, such as set top boxes, computers, game consoles, DVD players, CD players, etc. With the introduction of more components having increased processing capabilities and increased functionalities, which tend to produce more heat, the need for an improved thermal management system exists. An additional complication in the trend of electronic devices is the need to reduce the size of the device due to consumer preference. This trend for compactness in combination with increased capabilities and functionalities results in a concentration of heat generation in the electronic device.

The challenge of thermal management is further complicated by the need to provide EMI shielding, otherwise referred to as radio frequency (RF) shielding, around one or more of the signal processing components mounted to the PCB in an electronic device. The shielding is needed for preventing undesired RF signals from the signal processing components interfering with the operation of other components and/or for preventing undesired RF signals from other sources interfering with the operation of the signal processing components. Although a surface of the RF shield may serve as part of a thermal interface for heat conduction away from one or more components enclosed within, the RF shield also tends to limit airflow to components inside the RF shield causing a rise in the ambient temperature.

Several approaches have been developed to address the simultaneous need for thermal management and RF shielding of key components in an electronic device. One such approach involves creating a thermal interface component stack between a key component mounted to the PCB inside the RF shield and a heat spreader or heatsink structure located outside of the RF shield. A first thermal conduction pad, typically made from silicone and ceramic materials, is placed within the space between the top surface of the key component and the bottom or inside surface of a portion of the RF shield. A second thermal conduction pad is placed on the top or outside surface opposite the first thermal conduction pad. A heat spreader or heatsink is attached to the other surface of the second thermal conduction pad. In order to facilitate placement of the thermal conduction pads and/or the heat spreader or heatsink, the portion of the RF shield may be indented with respect to the remainder of the RF shield surface. In some cases, the thermal interface component stack may be secured with a fastening mechanism coupling the heat spreader or heatsink to the PCB. Further, if necessary, a mechanism to electrically couple or connect the heat spreader or heatsink to either the RF shield or the PCB may be included.

Although the above mentioned approach, as well as other similar approaches, may be effective in providing RF shielding and thermal management, drawbacks still exist with respect to other design considerations. The thermal interface component stack is potentially less thermally efficient due to the plurality of surface interfaces between the two thermal conduction pads. The process for assembling the thermal interface component stack described above can also be more complicated to assemble and perhaps more labor intensive. Quality control with respect to the placement of the two thermal conduction pads may also be problematic. Further the need to manage and handle the two thermal conduction pads adds to the expense of the electronic device. Therefore, a need exists for an improved thermal conduction structure for components in an electronic device that require both RF shielding and thermal management.

### SUMMARY

These and other drawbacks and disadvantages presented by electrical or electronic devices requiring both thermal management and EMI shielding are addressed by the principles of the present disclosure. However, it can be understood by those skilled in the art that the present principles may offer advantages in other types of devices and systems as well.

According to an implementation, an apparatus is described. The apparatus includes a shield enclosing at least one component attached to a printed circuit board, the shield having an inner surface and an outer surface, the at least one component having an outer surface aligned in parallel with the inner surface of the shield, the shield including at least one opening extending through the shield from the outer surface to the inner surface and aligned with the at least one component. The apparatus further includes a heatsink positioned adjacent to the outer surface of the shield and aligned with one of the at least one component, the heatsink thermally coupled to the outer surface of the at least one component using flowable thermally conductive material, such that the flowable thermally conductive material extends through the at least one opening and occupies a space between the outer surface of the at least one component and the inner surface of the shield and occupies a space between the outer surface of the shield and a surface of the heatsink.

According to an implementation, an electronic device is described. The electronic device includes a casing, a printed circuit board enclosed within the casing, and a heatsink assembly. The heatsink assembly includes a shield enclosing at least one component attached to a printed circuit board, the shield having an inner surface and an outer surface, the at least one component having an outer surface aligned in parallel with the inner surface of the shield, the shield including at least one opening extending through the shield from the outer surface to the inner surface and aligned with the at least one component. The heatsink assembly further includes a heatsink positioned adjacent to the outer surface of the shield and aligned with one of the at least one component, the heatsink thermally coupled to the outer surface of the at least one component using flowable thermally conductive material, such that the flowable thermally conductive material extends through the at least one opening and occupies a space between the outer surface of the at least one component and the inner surface of the shield and a space between the outer surface of the shield and a surface of the heatsink.

### BRIEF DESCRIPTION OF THE DRAWINGS

The above and other aspects, features, and advantages of the present disclosure will become more apparent in light of the following detailed description when taken in conjunction with the accompanying drawings in which:

FIG. 1 is a first perspective view of a portion of an electronic device to which the principles of the present disclosure are applicable;

FIG. 2 is a second perspective view of a portion of an electronic device to which the principles of the present disclosure are applicable;

FIG. 3 is a perspective view of a heatsink assembly to which the principles of the present disclosure are applicable;

FIG. 4 is a cross-sectional view of the heatsink assembly of FIG. 3 to which the principles of the present disclosure are applicable;

FIG. 5 is a perspective view of a portion of an exemplary heatsink assembly during the assembly process to which the principles of the present disclosure are applicable;

FIG. 6 is a graph showing the shielding effectiveness versus frequency for an exemplary heatsink assembly to which the principles of the present disclosure are applicable; and

FIG. 7 is a flow chart of an exemplary process for assembling a heatsink assembly used in an electronic device to which principles of the present disclosure are applicable.

### DETAILED DESCRIPTION

The present disclosure may be applicable to electronic apparatuses or devices described as being assembled apparatuses or devices having a plurality of walls along with some type of internal EMI or RF shielding structure and a heat management system or mechanism including one or more heatsinks. The present disclosure also addresses how the heat management system or mechanism including one or more heatsinks may be incorporated into an assembly process for the electronic apparatuses and devices.

The present description illustrates the principles of the present disclosure. It will thus be appreciated that those skilled in the art will be able to devise various arrangements which, although not explicitly described or shown herein, embody the principles of the present disclosure and are included within the scope of the claims.

All examples and conditional language recited herein are intended for pedagogical purposes to aid the reader in understanding the principles of the present disclosure and the concepts contributed by the inventor(s) to furthering the art and are to be construed as being without limitation to such specifically recited examples and conditions.

Moreover, all statements herein reciting principles, aspects, and embodiments of the principles of the present disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

In the embodiments hereof, any element expressed or described, directly or indirectly, as a means for performing a specified function is intended to encompass any way of performing that function including, for example, a) a combination of elements that performs that function or b) any mechanism having a combination of electrical or mechanical elements to perform that function. The disclosure as defined by such claims resides in the fact that the functionalities provided by the various recited means are combined and brought together in the manner which the claims call for. It is thus regarded that any means that can provide those functionalities are equivalent to those shown herein.

The present embodiments address problems associated with efficiently producing and using a mechanical structure that is required to provide thermal management or heat dissipation as well as RF signal shielding for one or more electrical or electronic components in an electrical or electronic device. In the past, the need to simultaneously meet thermal design requirements and EMI or RF shielding requirements has led to mechanical structures that can be more difficult to produce and/or assemble.

The present disclosure addresses these problems by focusing on embodiments that utilize a thermal interface component stack that provides efficient thermal energy transfer from an electronic component inside a shield structure to a heat spreader or heatsink outside of the shield structure while still also providing the necessary RF shielding and in a simplified mechanical structure. The embodiments are particularly useful in devices or systems where one electrical or electronic component is required to be enclosed in RF shielding along with other electrical or electronic components and the one electrical or electronic component is also a primary source of heat generation that requires some form of thermal management.

The embodiments take advantage of certain aspects associated with thermal interface material (TIM) and, in particular, flowable thermally conductive material, such as thermal putty. These aspects include, but are not limited to, being easily dispensable, having a high tack surface, and having high conductivity resulting in a low thermal impedance. In order to apply the TIM or flowable thermally conductive material, one or more openings are included in the shield above the location of the electrical or electronic component(s) that require thermal management. The TIM or flowable thermally conductive material is applied to fill a space that is created between the top surface of the electrical or electronic components and the inside or bottom surface of the RF shielding as well as a space between the outer or top surface of the RF shielding and the bottom surface of one or more heat spreaders or heatsinks located outside of the RF shielding. The TIM or flowable thermally conductive material may be dripped or otherwise dispensed putty into one or more openings or holes that are included in the RF shielding in a sufficient amount such that the TIM or flowable thermally conductive material fills the space inside the RF shielding is further dripped or dispensed onto the top surface of the RF shielding to be used to fill the space outside the RF shielding. During assembly, the TIM or flowable thermally conductive material that is dripped or dispensed outside the RF shielding may be squeezed flat between the RF shielding and the one or more heat spreaders or heatsinks. The openings or holes are designed such that they do not impact the performance of the RF shielding based on the EMI requirements of the electrical or electronic component.

The present embodiments illustrate several of the advantages present in the embodiments that are described below. These advantages include, but are not limited to, use of a single TIM rather than two or more instances of TIM or thermal pads to interface between an RF shielded electrical or electronic component and a heat spreader or heatsink. Additionally, thermal conduction between the electrical or electronic component and the heat spreader or heatsink is improved, which may potentially reduce the size requirements for the heat spreader of heatsink. Also, the assembly or manufacturing process is simplified. Still further, no extra cost is incurred with respect to the RF shielding structure having to accommodate a thermal management mechanism.

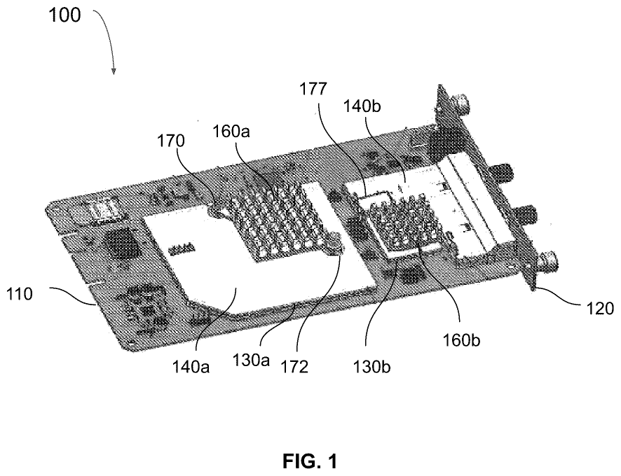

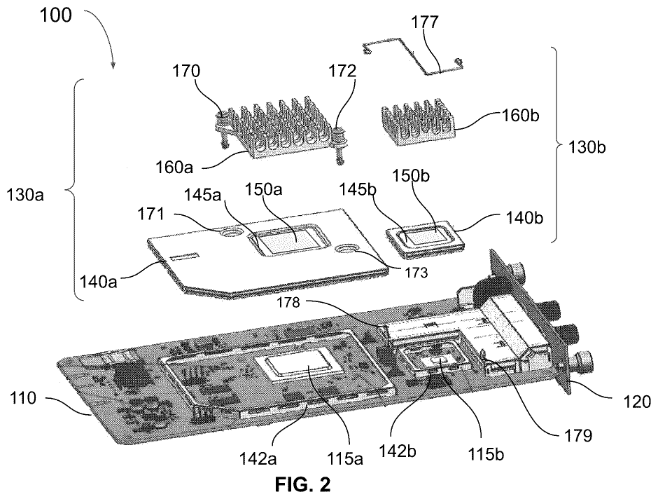

Turning to FIGS. 1 and 2, two views of an exemplary electronic device 100 including an RF shielding and thermal management mechanism according to aspects of the present disclosure are shown. It is important to note that although electronic device 100 may be shown as having a particular shape, electronic device 100 may take on a shape other than that shown without deviating from the principles of the present disclosure. The same reference numbers will be maintained throughout the description of FIGS. 1 and 2.

FIG. 1 shows a first perspective view of the inside structure of a portion of an exemplary electronic device 100 according to principles of the disclosure. The electronic device 100 may be, but is not limited to, a set top box, a computer, a game console, a cellular phone, a digital versatile disk (DVD) player, and a compact disk (CD) player. The electronic device 100 includes at least one printed circuit board (PCB) 110, two heatsink assemblies 130a, 130b and a faceplate 120 assembled in a casing (not shown) for electronic device 100. One edge of the PCB 110 is attached to a surface of the faceplate 120 when the electronic device 100 is assembled.

Each heatsink assembly 130a, 130b includes a shield 140a, 140b and a heatsink 160a,160b. The shields 140a, 140b are formed from a material suitable for protecting electrical or electronic components located within the shields 140a, 140b from RF interference. An example of a suitable material may be a metal, such as plated steel or zinc alloy steel. Generally, those skilled in the art will appreciate that the shield functions primarily to shield radio frequency interference from radiating to surrounding components from components contained within the shield, or to shield radio frequency interference generated outside the shield from affecting those components within the shield. It is important to note that electronic device 100 may include other shields or shielding structures that are not part of a heatsink assembly when the components within those shields or shielding structures do not require additional thermal management or heat dissipation.

The heatsinks 160a, 160b dissipate the heat generated by components located on PCB 110 by radiating the heat into the air surrounding heatsinks 160a, 160b, thereby allowing some regulation of the temperature the components thermally interfaced to heatsinks 160a, 160b during use and operation. Heatsinks 160a, 160b are oversized structures typically formed from a metal, such as copper or aluminum, and designed to maximize the surface area in contact with the air. In one exemplary embodiment, each of the heatsinks 160a, 160b may have a plurality of fins protruding upward from a solid base. The plurality of fins maximizes the surface area in contact with air flow within the case of electronic device 110 in order to promote component cooling.

As shown, heatsink assembly 130a includes compression spring pin fasteners 170 and 172 for attachment of heatsink assembly 130a to PCB 110. The compression spring pin fasteners 170 and 172 attach to PCB 110 through openings (not shown) that are aligned between the heatsink 160a, shield 140a, and PCB 110. The compression spring pins fasteners 170 and 172 typically have a flexible barb at the end that engages with the opening in PCB 110 to retain the pin portion of the fastener. The compression spring pin fasteners 170 and 172 hold the heatsink assembly 130a together and maintain contact between the heatsink 160a and a component (not shown) on PCB 110 through a flowable thermally conductive material (not shown) that is placed in a space between the component and the inside surface of shield 140a as well as the outside surface of shield 140a and bottom surface of heatsink 160a. Heatsink assembly 130b includes a spring clip fastener 177 that extends over a portion of heatsink assembly 130b and is attached at either end to posts attached to the surface PCB 110. The spring clip fastener 177 flexibly holds heatsink assembly 130b together and maintains contact between the heatsink 160b and another component (not shown) on PCB 110 in a manner similar to that described above.

It is worth noting that compression spring pin fasteners 170 and 172 and spring clip fastener 177 represent two alternative mechanisms for attaching and securing a heatsink assembly (e.g., heatsink assembly 130a, 130b) to a PCB (e.g., PCB 110). Other mechanisms and structures are possible as are well known by those skilled in the art. The other mechanisms and structures may be used in conjunction with the various embodiments while still taking advantage of various aspects of the present disclosure. It is also worth noting that not all heatsink assemblies may require attachment to a PCB or use fasteners as described here.

FIG. 2, shows an exemplary exploded view of the assembly of a subset of components for the inside structure of a portion of an exemplary electronic device 100 according to principles of the disclosure. More specifically, FIG. 2 includes an exemplary exploded view of heatsink assembly 130a and heatsink assembly 130b. Heatsink assembly 130a includes a shield 140a, an indentation portion 145a, a flowable thermally conductive material 150a, a heatsink 160a, and fasteners 170 and 172. Heatsink assembly 130b includes a shield 140b, an indentation portion 145b, a flowable thermally conductive material 150b, a heatsink 160b and a fastener 177.

For one or more portions of the PCB 110, a plurality of electrical and/or optical components are placed inside the area covered by shields 140a and 140b including component 115a and component 115b respectively. The components, including components 115a and 115b may be soldered and/or bonded with an epoxy to the PCB. Shield frames 142a and 142b are attached to the PCB 110. Each shield frame 142a, 142b surrounds a portion of the plurality of electrical and/or optical components, including components 115a and 115b respectively, requiring heat dissipation and shielding from frequency interference. Shield frames 142a, 142b are attached to the PCB 110 with tabs (not shown) that protrude through to the underside of PCB 110. The shield frames 142a, 142b are coupled to shields 140a, 140b respectively to enclose or surround the plurality of electrical and/or optical components requiring heat dissipation as well as shielding from radio frequency interference. A mechanical coupling between shield frames 142a, 142b and shields 140a, 140b may be realized using a series of spring fingers along the edges, and oriented perpendicular to, the surface of shields 140a,140b. The fingers are snapped over the outer surface of the shield frames 142a, 142b to form an electrically connected and mechanically secure coupling. Generally, those skilled in the art will appreciate that the shield functions primarily to shield radio frequency interference from radiating to surrounding components from components contained within the shield, or radio frequency interference generated outside the shield from affecting those components within the shield.

The shield frames 142a, 142b are formed from a material suitable for protecting components from RF interference in a manner similar to that described for the shields 140a,140b above. Examples of a suitable material for shield frames 142a, 142b include plated steel or zinc alloy steel. The shields 140a, 140b have a topographic surface that is generally planar with respect to the surface of the PCB 110. The topographic surface provides a suitable height for the shields 140a, 140b when they are coupled to the shield frames 142a, 142b providing clearance to the underlying electrical and/or optical components as necessary. The topographic surface of shields 140a, 140b may also include one or more indentations to allow for interface with one or more electrical and/or optical components mounted on the PCB 110. Specifically, indentations 150a and 150b are included in shields 140 a, 140b respectively to provide an interface point between each of shields 140a, b and components 115a, b respectively to facilitate thermal transfer to heatsinks 160a, b located outside of shields 140a, 140b. It is worth noting that in some embodiments the inclusion of contours or indentations, such as indentation 145a and/or indentation 145b, in a shield may not be necessary based on the space or distance between the top of the component and the bottom or inside surface of the shield.

An amount of flowable thermally conductive material 150a, 150b is placed directly on top of the components 115a, 115b respectively through one or more openings (not shown) in the indentation regions 145a, 145b as part of shields 140a, 140b. The flowable thermally conductive material 150a, 150b may be a type of thermal putty or any other TIM that includes similar properties. Examples of flowable thermally conductive material 150a, 150b include, but is not limited to, TIM-PUTTY 418HTC form-in-place Thermally Conductive Gap filler putty by Timtronics Thermal Interface Materials and THERM-A-GAP™ GELS T630, T630G, T635, T636, T652, GEL8010, GEL30, & GEL30G by Parker Chomerics. The flowable thermally conductive material 150a, 150b may be placed on components 115a, 115b by injection or dispensing through the one or more openings (not shown) in the indentation regions 145a, 145b. The flowable thermally conductive material 150a, 150b may be placed on components 115a, 115b through the one or more openings after the shields 140a, 140b are assembled in place with shield frames 142a, 142b.

The amount of flowable thermally conductive material 150a, 150b is determined such that it is sufficient to fill any space that exists between the top surface of components 115a, 115b and the inner or bottom surface of indentations 142a, 142b. The amount of flowable thermally conductive material 150a, 150b is also sufficient to fill a space that is created between the outer or top surface of indentations 142a, 142b and the bottom surface of heatsinks 160a, 160b. When assembled, the space between the top surface of components 115a, 115b and the inner or bottom surface of indentations 142a, 142b as well as the space between the outer or top surface of indentations 142a, 142b and the bottom surface of heatsinks 160a, 160b may be between 1 millimeter (mm) and 5 mm. The flowable thermally conductive material 150a, 150b that is placed on the outer or top surface of indentations 145a, 145b is pressed smooth and flat by affixing heatsinks 160a, 160b as part of heatsink assemblies 130a, 130b. In some embodiments, the amount of flowable thermally conductive material 150a, 150b is sufficient to fill the entire span of indentations 145a, 145b in shields 140a, 140b with enough additional material to further fill a space created between the outer or top surface of shields 140a, 140b, and the bottom surface of heatsinks 160a, 160b outside the span of indentations 145a, 145b.

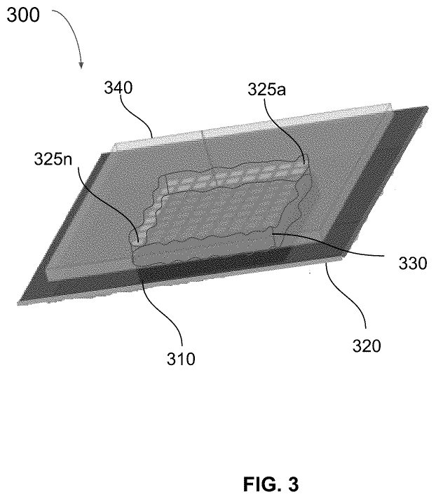

The thermal interface formed by the flowable thermally conductive material 150a, 150b coupling the top surface of components 115a, 115b to the bottom surface of heatsinks 160a, 160b through the one or more openings that are present in the region of indentations 145a, 145b facilitate strong heat transfer from the components 115a, 115b to the heatsinks 160a, 160b. Further details with respect to the implementation and use of the flowable thermally conductive material 150a, 150b in the heat assemblies 130a, 130b will be discussed below with reference to FIGS. 3-5.

Shield 140a also include openings 171 and 173 outside the span of indentation 145a and aligned with the position of compression spring pin fasteners 170 and 172 used with heatsink assembly 130a as described above. Retaining clips 178 and 179 are shown extending from PCB 110 outside of the shield 140b and shield frame 142b. The retaining clips 178 and 179 are positioned to capture the ends of spring clip fastener 177 used with heatsink assembly 130b as described above.

As described in FIGS. 1-2, the amount of flowable thermally conductive material 150a, 150b is sufficient to fill a space or gap between that is created between the outer or top surface of indentations 145a, 145b, as well as the outer or top surface of shields 140a, 140b in some cases, and the bottom surface of heatsinks 160a, 160b. As a result, shields 140a, 140b are electrically isolated from heatsinks 160a, 160b. In some embodiments, it may be desirable for a portion of the bottom surface of one or both heatsinks 160a, 160b to be electrically coupled to the outer or top surface of the shields 140a, 140b respectively (e.g., outside of the span of indentations 145a, 145b). By coupling one or both heatsinks 160a, 160b to shields 140a, 140b electrically as well as thermally the heatsink(s) will be at the same electrical potential (e.g., ground potential) as the shield(s). As a result, the electrical coupling may improve RF or EMI shielding performance. The electrical coupling may be realized through a mechanical arrangement, such as the two surfaces being pressed together. Alternatively, the electrical coupling may be realized by a bonding mechanism, such as soldering.

It is worth noting that the elements of heatsink assemblies 130a, 130b are described in FIGS. 1-2 as primarily horizontally oriented with elements interfacing using top and bottom surfaces. However, one or more of the principles of the present embodiments may be equally applicable to heatsink assemblies that are vertically oriented, with the elements referencing left and right side surfaces rather than top and bottom surfaces. Further, electronic device 100 is shown as including two heatsink assemblies. In other embodiments, electrical or electronic devices may include more or fewer heatsink assemblies.

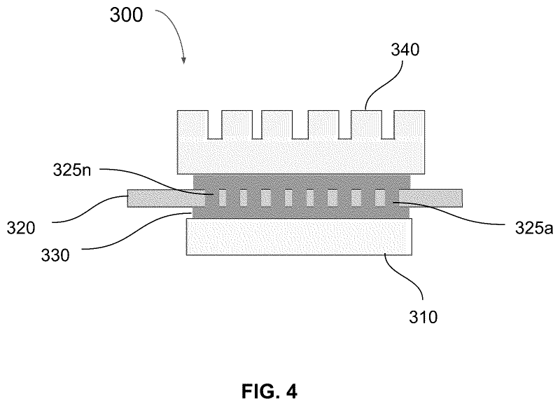

Turning to FIGS. 3-4, two views of an exemplary heatsink assembly 300 according to aspects of the present disclosure are shown. Heatsink assembly 300 may be included in a thermal dissipation and shielding mechanism utilized as part of any electrical or electronic device, such as electronic device 100 described in FIGS. 1-2. Heatsink assembly 300 primarily describes a thermal interface component stack or structure that does not require a contour or indentation in the surface of the shield as described above. However, the principles below apply equally to other thermal interface structures such as described for heatsink assemblies 130a, 130b above. It is to be appreciated that several components and elements necessary for complete functionality of the heatsink assembly 300 in an electrical or electronic device, including those described above, are not shown in the interest of conciseness, as some of these components and elements not shown are well known to those skilled in the art. The same reference numbers will be maintained throughout the description of FIGS. 3-4.

FIG. 3 shows a perspective view of the structure of an exemplary heatsink assembly 300 according to principles of the disclosure. The perspective view of heatsink assembly 300 is shown with certain elements as transparent and shaded in order to better understand the structure and interfacing of the elements within the heatsink assembly 300. Heatsink assembly 300 includes a component 310 with a portion of a shield 320 shown above the top surface of component 310. The portion of shield 320 may be a shield structure similar to shield 140a or shield 140b shown in FIGS. 1-2 but without indentations 145a, 145b. Shield 320 includes a plurality of openings 325a-325n directly above component 310. A portion of a heatsink 340 is shown above the top surface of the portion of shield 320 covering a region including the plurality of openings 325a-325n. Flowable thermally conductive material 330 is shown in the space between the top surface of component 310 and the bottom surface of heatsink 340, filling the plurality of openings 325a-325n in shield 320.

FIG. 4 shows a cross-sectional view of the structure of the exemplary heatsink assembly 300 according to principles of the disclosure. The cross-sectional view is shown through the center of heatsink assembly 300. The elements in heatsink assembly 300 shown in FIG. 4 have been shaded in a manner similar to FIG. 3. As in FIG. 3, shield 320 is shown above the top surface of component 310 and heatsink 340 is shown above the top surface of shield 320. Flowable thermally conductive material 330 is shown filling the space between the top surface of component 310 and the bottom surface of shield 320 as well as the top surface of shield 320 and the bottom surface of heatsink 340. The flowable thermally conductive material 330 also fills the plurality of openings 325a-325n allowing interface continuity between the top surface of component 310 below shield 320 and the bottom surface of heatsink 340 above shield 320.

All of the plurality of openings 325a-325n may be square in shape. In other embodiments, the plurality of openings 325a-325n may be all round or all triangular or may be a combination of any of the three shapes. The plurality of openings 325a-325n may in some cases be rectangular, however rectangular openings create additional design constraints with respect to RF shielding performance or effectiveness over a wide frequency range. In general, the size of, as well as the distance or spacing between each of. the plurality of openings 325a-325n may be determined primarily based on the frequency range over which the RF performance or effectiveness is required. The size of, or distance or spacing between each of, the plurality of openings 325a-325n may additionally be determined partly based on the required value for the RF shielding performance or effectiveness. The size, distance, or spacing may also be partly based on the thermal management requirements for the component (e.g., component 310). The size, distance, or spacing may further be partly based on the properties of the flowable thermally conductive material along with the dispensing equipment used. In some embodiments, the size of and/or the spacing between each of the plurality of openings 325a-325n may be non-uniform and/or non-symmetrical as long as all requirements for both thermal management performance and RF shielding performance are met.

As shown in FIGS. 3-4, the plurality of openings 325a-325n are square with a nominal length of 1 mm and a spacing of 0.5 mm. In other embodiments, depending on the required RF shielding performance requirements, the plurality of openings may range from 1 mm to 2 mm and spacing may range from 0.5 mm to 2 mm. Further, it may be useful to place openings no closer than 1.5 mm from an edge of the top surface of the component (e.g., component 310) in order to mitigate dispensing flowable thermally conductive material beyond or over that edge.

It is worth noting that even with the addition of the plurality of openings 325a-325n, the RF or EMI shielding performance of shield 320, along with other nominal components (e.g., shield frame 142a, b in FIGS. 1-2) still achieves signal level attenuation of 50 decibels (dB) or better over a wide range of frequencies. As described above, design tradeoffs may exist with respect to the RF or EMI shielding performance and the thermal management performance, as well as the amount of flowable thermally conductive material used. and the ease of assembly or manufacturing. These design tradeoffs may be used to determine the size of, spacing between, and/or the number of openings in the shield. Any of these variations created based on the design tradeoffs are within the scope of the present disclosure.

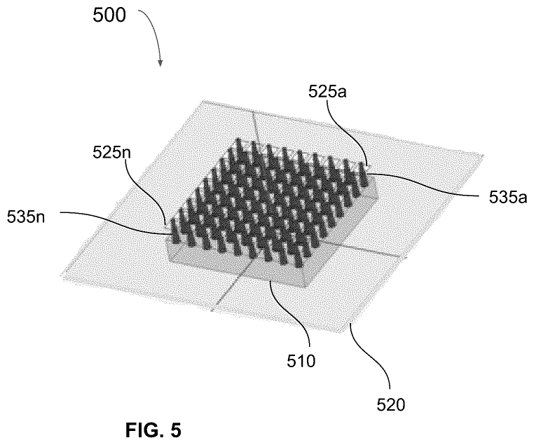

Turning to FIG. 5, a perspective view of a portion of an exemplary heatsink assembly 500 during the assembly process according to aspects of the present disclosure is shown. The perspective view of heatsink assembly 500 is shown with certain elements as transparent and shaded in order to better understand the structure and interfacing of the elements within the heatsink assembly 500. Unless otherwise described below, the structure and function of component 510, shield 520, and plurality of openings 525a-525n are the same as described above in FIGS. 3-4 for component 310, shield 320, and plurality of openings 325a-325n.

Heatsink assembly 500 includes a component 510 with a portion of a shield 520 shown above the top surface of component 510. Shield 520 includes a plurality of openings 525a-525n directly above component 510. At a point during assembly of the electronic device (e.g., electronic device 100 shown in FIGS. 1-2), component 510 is affixed to the PCB (e.g., PCB 110) and the shield 520 is positioned and affixed (e.g., using shield frame 142a, 142b) above the component 510. After this point during assembly of heatsink assembly 500 and before a heat spreader or heatsink (e.g., heatsink 340 in FIG. 3) is positioned above the shield 520, flowable thermally conductive material is dispensed as drops 535a-535n through each of the plurality of openings 525a-525n. The drops 535a-535n, which may also be referred to as puddles or beads, of flowable thermally conductive material may be dispensed using a hand operated or a machine operated dispensing device. The amount of flowable thermally conductive material may be determined based on the space that is present between the top surface of component 510 and the bottom surface of shield 520 as well as the space that will be present between the top surface of shield 520 and the bottom surface of a heat spreader of heatsink. In some embodiments, not all of the plurality of openings 525a-525n have drops, puddles, or beads of flowable thermally conductive material dispensed through them. As such, the number of drops, puddles, or beads od flowable conductive material may be dispensed through a subset of the openings 525a-525n.

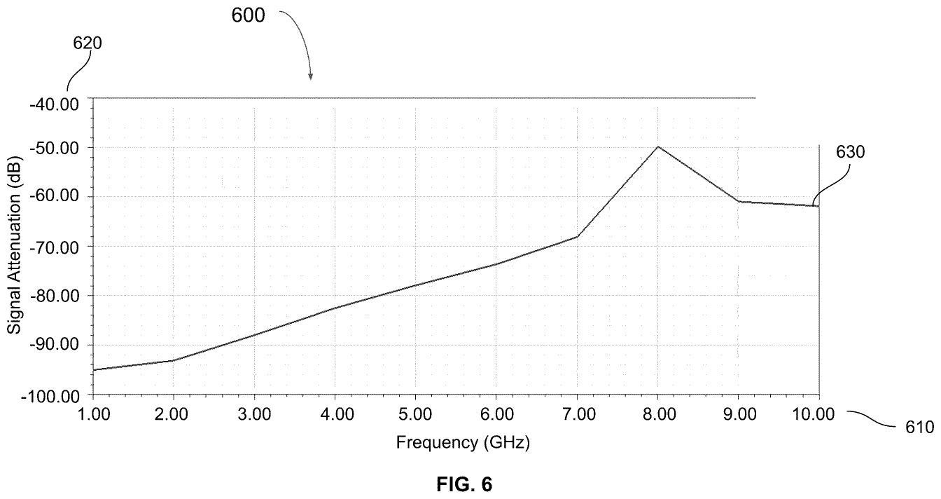

Turning to FIG. 6, a graph 600 showing the shielding effectiveness versus frequency for an exemplary heatsink assembly according to aspects of the present disclosure is shown. Graph 600 is generated using a simulation tool, such as high frequency simulation software (HFSS) from Ansys. Graph 600 includes a horizontal axis 610 displaying signal frequency, in gigahertz (GHz), and a vertical axis 620 displaying signal attenuation level, expressed in decibels (dB). Graph 600 further includes a signal waveform 630, representing the signal attenuation as result of the presence of a shielding structure similar to shield 320 along with openings 325a-325nn using the opening size and spacing dimensions as described above. Signal waveform 630 indicates that signal attenuation due to the presence of a shielding structure, referred to as shielding effectiveness, is greater than 50 dB over a frequency range from 1 GHz to 10 GHz.

It is worth noting that an ideal shielding structure, one with no openings constructed from a proper metal and having proper thickness can create 100 percent RF or EMI shielding effectiveness (e.g., infinite dB). The introduction of any imperfection in the shielding structure, such as openings for affixing to a PCB or for the interface between a shield and a shield, reduce the shielding effectiveness to less than 100 percent. The introduction of one or more holes or openings (e.g., openings 325a-325n) specifically as described herein is important to the present disclosure to facilitate the use of a single common thermal interface between the component that is enclosed in the shield and the heat spreader or heatsink that is outside the shield. While the introducing of the one or more openings degrades shielding effectiveness, the design tradeoffs can be managed in such a manner as to create an improved heatsink assembly that achieves the desired thermal management performance as well as RF or EMI shielding effectiveness.

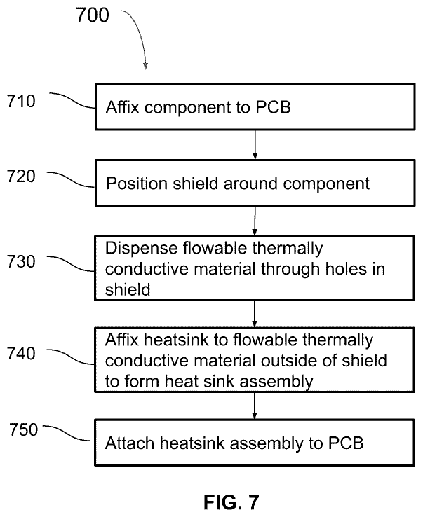

Turning to FIG. 7, a flow chart of an exemplary process 700 for assembling a heatsink assembly used in an electronic device according to aspects of the present disclosure is shown. Process 700 will be primarily described with respect to the heatsink assembly 300 described in FIGS. 3-4. Process 700 may also apply to heatsink assemblies used in electrical or electronic devices, such as electronic device 100 described in FIGS. 1-2. Further, some aspects of process 700 may also be utilized as part of assembling or manufacturing heatsink assemblies such as heatsink assembly 500 described in FIG. 5. Although process 700 depicts steps performed in a particular order for purposes of illustration and discussion, the operations discussed herein are not limited to any particular order or arrangement. Further, while process 700 is described in association with heatsink assemblies typically used in electrical or electronic devices, process 700 may easily be adapted for use in other assemblies and other devices requiring thermal management in conjunction with other requirements, such as EMI shielding, that may present thermal management challenges. One skilled in the art, using the disclosure provided herein, will also appreciate that one or more of the steps of process 700 may be omitted, rearranged, combined, and/or adapted in various ways.

At step 710, as part of an assembly process, a component that requires both RF or EMI shielding and thermal management, such as component 310, is affixed to a PCB (e.g., PCB 110 described in FIGS. 1-2). The affixing of the component may include epoxying the body of the component to the PCB to mechanically stabilize the component on the PCB. The affixing, at step 710, may also include soldering one or more leads of the component to the PCB. The soldering may include applying heat to a solder paste pattern, liquid wave soldering, or hand soldering. Also, at step 710 additional components, including a shield frame (e.g., shield frame 142a, 142b) may be affixed to the PCB in a similar manner as described here.

At step 720, a shield, such as shield 320, is positioned around the component affixed to the PCB, at step 710. In order to best facilitate thermal management of the component, an inner surface of the shield is aligned to be parallel with the outer surface of the component, without contacting the component. In some embodiments, a portion of the shield is aligned such that the inner or bottom surface of the portion of the shield is above the outer or top surface of the component. As part of step 720, the shield may be mechanically and/or electrically affixed to the PCB as part of stabilizing its position around the component. In some embodiments, the shield is mechanically attached to a shield frame.

The shield (e.g., shield 320) that is positioned around the component, at step 720, includes one or more openings or holes, such as the set of openings 325a-325n. The openings are positioned on the surface of the portion of the shield that is aligned (e.g., above) with the component. The openings may be square, circular, and/or triangular. The size of, and spacing or distance between, the openings or holes may be determined based on the requirements for the RF or EMI performance as well as the requirements for the thermal management performance as described above.

At step 730, flowable thermally conductive material is dispensed through the one or more openings in the shield that are aligned with the component. The flowable thermally conductive material 150a, 150 b may be a type of thermal putty or any other TIM that includes similar properties as described above. The flowable thermally conductive material may be dispensed using a hand operated or a machine operated dispensing device. The amount of flowable thermally conductive material may be determined based on the volume of material needed to fill the space between the top surface of the component and the inner surface of the shield.

The flowable thermally conductive material is further dispensed to provide material to create an interface surface that forms a gap or space between the outer surface of the shield and a surface of a heatsink that is affixed to the shield through the flowable thermally conductive material, at step 740. The heatsink is positioned in alignment with the component but outside or above the outer surface of the shield. As part of the affixing of the heatsink, at step 740, the heatsink may be pressed or otherwise adjusted with force to be close to, but not electrically contacting or coupled to, the outer surface of the shield. As a result of steps 730 and 740, the flowable thermally conductive material forms a single layer thermal conductor both inside (i.e. below) and outside (i.e. above) the shield through the one or more openings that serves as a thermal interface between the component and the heatsink.

At step 750, the heatsink assembly including the shield, the flowable thermally conductive material, and the heatsink, is affixed, or attached to the PCB. The attachment mechanism may include one or more fasteners that are interfaced to one or more of the elements of the heatsink assembly as described above. The fasteners may include, but are not limited to, compression spring pins (e.g., compression spring pin fasteners 170, 172), spring clips (e.g., spring clip fastener 177), and other similar mechanisms.

As an example of the use of process 700 to assemble a heatsink assembly, a shield is positioned vertically above a component oriented horizontally on a PCB. Flowable thermally conductive material is dispensing through and above a plurality of openings in the shield that are uniformly spaced above the component. A heatsink is affixed to the flowable thermally conductive material that is present above the plurality of openings. The amount of flowable thermally conductive material is such that it fills a gap that is present between the top of the component and the bottom surface of the shield as well as a gap that is present between the top surface of the shield and the bottom surface of the heatsink.

In some embodiments, the shield that is positioned around the component, at step 720, may include an indentation (e.g., indentations 145a, 145b in FIGS. 1-2) in the surface of the portion of the shield aligned with the component. The indentation may be used as part of alignment of other elements, such as a heat spreader or heat sink. The indentation may be used to reduce the distance or space between the outer or top surface of the component and the inner or bottom surface of the shield when other components enclosed in the shield require additional height above the PCB. The indentation may also be used for containment of material, such as flowable thermally conductive material.

It is important to note that in some embodiments, the dispensing at step 730 may involve dispensing the flowable thermally conductive material directly to the outer or top surface of the component prior to positioning the shield around the component, at step 720. As the shield is positioned or aligned with the component, the flowable thermally conductive material is squeezed or extruded through the one or more openings in the shield. As a further adjustment, additional flowable thermally conductive material may be added to the outer or top surface of the shield as needed to affix the heatsink, at step 740. This modification of process 700 results in the same final arrangement or configuration of the heatsink assembly (e.g., heatsink assembly 300).

The above embodiments describe an apparatus for providing thermal management and RF or EMI shielding as well as a method for assembly of the apparatus. The apparatus, or heat sink assembly, offers several advantages over previous heatsink assemblies that also provide RF or EMI shielding. One advantage is the use of a single TIM, such as a flowable thermally conductive material, that bridges the interface between a component requiring thermal management within an EMI or RF shield and a heatsink outside the EMI or RF shield without significantly impacting EMI or RF shielding performance. The use of a single TIM reduces cost and also simplifies assembly or manufacturing over designs that utilize multiple interfaces and materials. Further, in some cases, the thermal transfer between the component and the heatsink is improved allowing the use of a smaller heatsink with the same thermal management performance. The apparatus or heatsink assembly is also easily adaptable to different component sizes and shapes as needed.

According to the present disclosure, an apparatus is described that includes a shield enclosing at least one component attached to a printed circuit board, the shield having an inner surface and an outer surface, the at least one component having an outer surface aligned in parallel with the inner surface of the shield, the shield including at least one opening extending through the shield from the outer surface to the inner surface and aligned with the at least one component. The apparatus further includes a a heatsink positioned adjacent to the outer surface of the shield and aligned with one of the at least one component, the heatsink thermally coupled to the outer surface of the at least one component using flowable thermally conductive material, such that the flowable thermally conductive material extends through the at least one opening and occupies a space between the outer surface of the at least one component and the inner surface of the shield and occupies a space between the outer surface of the shield and a surface of the heatsink.

In some embodiments, the apparatus may be referred to as a heatsink assembly.

According to the present disclosure, an electronic device is described that includes a casing, a printed circuit board enclosed within the casing, and a heatsink assembly. The heatsink assembly includes a shield enclosing at least one component attached to a printed circuit board, the shield having an inner surface and an outer surface, the at least one component having an outer surface aligned in parallel with the inner surface of the shield, the shield including at least one opening extending through the shield from the outer surface to the inner surface and aligned with the at least one component. The heatsink assembly further a heatsink positioned adjacent to the outer surface of the shield and aligned with one of the at least one component, the heatsink thermally coupled to the outer surface of the at least one component using flowable thermally conductive material, such that the flowable thermally conductive material extends through the at least one opening and occupies a space between the outer surface of the at least one component and the inner surface of the shield and a space between the outer surface of the shield and a surface of the heatsink.

In some embodiments, the electronic device is a set top box.

In some embodiments, the at least one opening is a plurality of openings spanning at least a portion the surface of the shield and aligned with the at least one component.

In some embodiments, each one of the plurality of openings is in the shape of at least one of a square, a circle, and a triangle.

In some embodiments, each one of the plurality of openings is in the shape of a square, the length of each one of the set of openings being determined based on at least one radio frequency signal to be attenuated by the shield.

In some embodiments, each one of the plurality of openings is in the shape of a square, the distance between each one of the set of openings being determined based on a radio frequency signal to be attenuated by the shield.

In some embodiments, the flowable thermally conductive material that is present within the space between the shield and the heatsink further electrically isolates the shield from the heatsink.

In some embodiments, the shield further includes at least one indentation region on the surface of the shield and wherein the at least one opening is within the at least one indentation region.

In some embodiments, the apparatus or heatsink assembly further includes at least one fastener that attaches the shield and heatsink to the printed circuit board.

In some embodiments, the at least one fastener is one of a compression spring pin and a spring clip.

In some embodiments, the shield is mechanically coupled to a shield frame mounted to the printed circuit board.

It is to be appreciated that, except where explicitly indicated in the description above, the various features shown and described are interchangeable, that is, a feature shown in one embodiment may be incorporated into another embodiment.

Although embodiments which incorporate the teachings of the present disclosure have been shown and described in detail herein, those skilled in the art can readily devise many other varied embodiments that still incorporate these teachings. Having described preferred embodiments of an apparatus for providing thermal management and electromagnetic interference shielding, it is noted that modifications and variations can be made by persons skilled in the art in light of the above teachings. It is therefore to be understood that changes may be made in the particular embodiments of the disclosure which are within the scope of the disclosure as outlined by the appended claims.

1. A heatsink assembly comprising;
a shield enclosing at least one component attached to a printed circuit board intended to be enclosed within a casing of an electronic assembly, the shield having an inner surface and an outer surface, the at least one component having an outer surface aligned in parallel with the inner surface of the shield, the shield including at least one opening extending through the shield from the outer surface to the inner surface and aligned with the at least one component; and
a heatsink positioned adjacent to the outer surface of the shield and aligned with one of the at least one component, the heatsink thermally coupled to the outer surface of the at least one component using flowable thermally conductive material, such that the flowable thermally conductive material extends through the at least one opening and occupies a space between the outer surface of the at least one component and the inner surface of the shield and occupies a space between the outer surface of the shield and a surface of the heatsink.

2. The apparatus of claim 1, wherein the at least one opening is a plurality of openings spanning at least a portion the surface of the shield and aligned with the at least one component.

3. The apparatus of claim 2, wherein each one of the plurality of openings is in the shape of at least one of a square, a circle, and a triangle.

4. The apparatus of claim 3, wherein each one of the plurality of openings is in the shape of a square, the length of each one of the plurality of openings being determined based on at least one radio frequency signal to be attenuated by the shield.

5. The apparatus of claim 3, wherein each one of the plurality of openings is in the shape of a square, the distance between each one of the plurality of openings being determined based on at least one radio frequency signal to be attenuated by the shield.

6. The apparatus of claim 1, wherein the flowable thermally conductive material that is present within the space between the shield and the heatsink further electrically isolates the shield from the heatsink.

7. The apparatus of claim 1, wherein the shield further includes at least one indentation region on the surface of the shield and wherein the at least one opening is within the at least one indentation region.

8. The apparatus of claim 1, further comprising at least one fastener that attaches the shield and the heatsink to the printed circuit board.

9. The apparatus of claim 8, wherein the at least one fastener is one of a compression spring pin and a spring clip.

10. The apparatus of claim 1, wherein the shield is mechanically coupled to a shield frame mounted to the printed circuit board.

11. An electronic device comprising:
a heatsink assembly, comprising:
a shield enclosing at least one component attached to a printed circuit board enclosed within a casing of the electronic device, the shield having an inner surface and an outer surface, the at least one component having an outer surface aligned in parallel with the inner surface of the shield, the shield including at least one opening extending through the shield from the outer surface to the inner surface and aligned with the at least one component; and
a heatsink positioned adjacent to the outer surface of the shield and aligned with one of the at least one component, the heatsink thermally coupled to the outer surface of the at least one component using flowable thermally conductive material, such that the flowable thermally conductive material extends through the at least one opening and occupies a space between the outer surface of the at least one component and the inner surface of the shield and a space between the outer surface of the shield and a surface of the heatsink.

12. The electronic device of claim 11, wherein the at least one opening is a plurality of openings spanning at least a portion the surface of the shield and aligned with the at least one component.

13. The electronic device of claim 12, wherein each one of the plurality of openings is in the shape of at least one of a square, a circle, and a triangle.

14. The electronic device of claim 13, wherein each one of the plurality of openings is in the shape of a square, the length of each one of the plurality of openings being determined based on at least one radio frequency signal to be attenuated by the shield.

15. The electronic device of claim 13, wherein each one of the plurality of openings is in the shape of a square, the distance between each one of the plurality of openings being determined based on at least one radio frequency signal to be attenuated by the shield.

16. The electronic device of claim 11, wherein the flowable thermally conductive material that is present within the space between the shield and the heatsink further electrically isolates the shield from the heatsink.

17. The electronic device of claim 11, wherein the shield further includes at least one indentation region on the surface of the shield and wherein the at least one opening is within the at least one indentation region.

18. The electronic device of claim 11, further comprising at least one fastener that attaches the shield and the heatsink to the printed circuit board.

19. (canceled)

20. The electronic device of claim 11, wherein the shield is mechanically coupled to a shield frame mounted to the printed circuit board.

21. The electronic device of claim 11, wherein the electronic device is a set top box.
